(19) United States
(12) Patent Application Publication
(10) Pub. No.: US 2023/0401347 A1
(43) Pub. Date: Dec. 14, 2023

(54) PLANT INFRASTRUCTURE MODELLING

(71) Applicant: Schneider Electric Industries SAS, Rueil-Malmaison (FR)

(72) Inventors: Xavier MOULIN, Antibes (FR); Scott BUMP, Idyllwild, CA (US); Philippe FARRUGIA, Vallauris (FR); Imran KHAN, Grenoble (FR); Raphaël CALVIGNAC, Grenoble (FR); Bernard BONY, Eybens (FR); Hervé JACQUET, Saint Paul de Varces (FR)

(73) Assignee: Schneider Electric Industries SAS, Rueil-Malmaison (FR)

(21) Appl. No.: 18/035,445

(22) PCT Filed: Oct. 11, 2021
(86) PCT No.: PCT/EP2021/078007

§ 371 Date: May 4, 2023

Related U.S. Application Data
(60) Provisional application No. 63/111,128, filed on Nov. 9, 2020.

(51) Int. Cl. G06F 30/13

(52) U.S. Cl. CPC G06F 30/13

(57) ABSTRACT

For providing a set of services relating to a semantic model of an infrastructure including assets belonging to different engineering domains, an application server: retrieves, for each engineering domain, asset identifiers respectively associated with assets of the engineering domain and with sets of attributes and for determining asset relationships between the asset identifiers; builds, for each engineering domain, an engineering domain model including assets identifiers that are linked between them based on the asset relationships; determines at least one asset identifier that belongs or is connected to at least two different engineering domain models and linking the at least two different engineering domain models via the at least one asset identifier to build a semantic model of the infrastructure; and provides a set of services for the semantic model of the infrastructure, the services using sets of attributes associated with asset identifiers that belong to different engineering domain models.

### FIELD OF INVENTION

The present invention generally relates to an infrastructure model like a industrial plant model for modelling plant items within an engineering environment.

### BACKGROUND

An infrastructure like a plant requires engineering in different domains (mechanical/Process/Electrical . . . ) with different disciplines per domain (Flow management, Hydraulic, Piping, Instrumentation for the process domain). Each domain or discipline is using dedicated model and tools to represent hardware or software assets. But there is no consistent model from one domain to the other, thus enforcing duplicated data, multiple import/export and high cost of engineering.

The infrastructure information is siloed by engineering discipline, each discipline relying on dedicated standards and data models, and cross-domain interactions have to rely on human expertise and exchanges.

There is therefore a need for an asset centric approach to easily exploit asset information from different engineering domains, for example for analytics and efficient maintenance.

### SUMMARY

This summary is provided to introduce concepts related to the present inventive subject matter. This summary is not intended to identify essential features of the claimed subject matter nor is it intended for use in determining or limiting the scope of the claimed subject matter.

In one implementation, there is provided a method for providing a set of services relating to a semantic model of a plant infrastructure comprising assets belonging to different engineering domains, the method comprising:
for each engineering domain, retrieving asset identifiers respectively associated with assets of the engineering domain and with sets of attributes and determining asset relationships between said asset identifiers,
for each engineering domain, building an engineering domain model comprising assets identifiers that are linked between them based on said asset relationships,
determining at least one asset identifier that belongs or is connected to at least two different engineering domain models and linking said at least two different engineering domain models via said at least one asset identifier to build a semantic model of the infrastructure,
providing a set of services for the semantic model of the infrastructure, the services using sets of attributes associated with asset identifiers that belong to different engineering domain models.

Advantageously, the information on the infrastructure, like a production plant, is not only expressed from the engineering domain point of view but offers to the owner and operator of the plant an asset centric vision of the infrastructure, allowing access to information on the asset context related to different engineering domains.

Advantageously, engineering cost is reduced drastically for the end user by eliminating duplicated effort for every engineering domain. There is only one reference for asset to be updated for example for operating and maintenance of the infrastructure.

In an embodiment, each engineering domain is associated with at least one dedicated application allowing access to information relating to at least one asset of the engineering domain by means of the sets of attributes associated with said at least one asset, and the set of services is delivered by dedicated applications associated with engineering domains.

Advantageously, the method allows to share engineering and asset information among different domains through dedicated applications and to move seamlessly from one application to another in asset context.

In an embodiment, asset relationships are categorized in at least two types of relationship including composition relationship and connection relationship, wherein composition relationship defines physical link between assets and connection relationship defines physical interaction between assets.

In an embodiment, the engineering domain model corresponds to a domain knowledge graph, wherein nodes correspond to asset identifiers and edges correspond to asset relationships between asset identifiers.

Advantageously, the model as a graph represents any kind of plant by modelling its various physical assets involved during all the lifecycle of the plant, from the engineering to operating and maintenance of the plant. The graph provides easy access to asset information from any view to any other view without expert knowledge. The graph also provides acceleration in diagnostic and decision making for equipment for example during operation and maintenance.

In an embodiment, a tool is provided to navigate through the domain knowledge graph and to interface with the dedicated applications of the engineering domains.

In an embodiment, the set of attributes of assets correspond to semantically meaningful elements.

In an embodiment, the asset relationship is defined by a triple composed of one asset, a relationship and another asset.

In an embodiment, each engineering domain is associated with a domain ontology defining the format of the set of attributes and of the asset relationships.

Advantageously, ontologies and semantic web technologies allow to reconcile the various discipline asset structures without imposing changes to these structures. This allows to create cross domain interoperability from design and build to operate and maintain phases with minimal effort.

Each asset is described in a plant knowledge graph using semantic web technology and has a simple web semantic property to launch different applications of interest: any software that may display a view of the asset. Each application can expose a mechanism to move easily between asset-related applications. Where possible, the invoked application can be opened in context to the asset of interest.

In another implementation, there is provided an application server for providing a set of services relating to a semantic model of an infrastructure comprising assets belonging to different engineering domains, the application server comprising:
means for retrieving, for each engineering domain, asset identifiers respectively associated with assets of the engineering domain and with sets of attributes and for determining asset relationships between said asset identifiers,
means for building, for each engineering domain, an engineering domain model comprising assets identifiers that are linked between them based on said asset relationships,
means for determining at least one asset identifier that belongs or is connected to at least two different engineering domain models and linking said at least two different engineering domain models via said at least one asset identifier to build a semantic model of the infrastructure,
means for providing a set of services for the semantic model of the infrastructure, the services using sets of attributes associated with asset identifiers that belong to different engineering domain models.

In another implementation, there is provided an apparatus for providing a set of services relating to a semantic model of an infrastructure comprising assets belonging to different engineering domains, the apparatus comprising:
one or more network interfaces to communicate with a telecommunication network;
a processor coupled to the network interfaces and configured to execute one or more processes; and
a memory configured to store a process executable by the processor, the process when executed operable to:
for each engineering domain, retrieve asset identifiers respectively associated with assets of the engineering domain and with sets of attributes and determining asset relationships between said asset identifiers,
for each engineering domain, build an engineering domain model comprising assets identifiers that are linked between them based on said asset relationships,
determine at least one asset identifier that belongs or is connected to at least two different engineering domain models and linking said at least two different engineering domain models via said at least one asset identifier to build a semantic model of the infrastructure,
provide a set of services for the semantic model of the infrastructure, the services using sets of attributes associated with asset identifiers that belong to different engineering domain models.

In another implementation there is provided a computer-readable medium having embodied thereon a computer program for executing a method for providing a set of services relating to a semantic model of an infrastructure comprising assets belonging to different engineering domains. Said computer program comprises instructions which carry out steps according to the method according to the invention.

### BRIEF DESCRIPTION OF THE FIGURES

The detailed description is described with reference to the accompanying figures. In the figures, the left-most digit(s) of a reference number identifies the figure in which the reference number first appears. The same numbers are used throughout the figures to reference like features and components. Some embodiments of system and/or methods in accordance with embodiments of the present subject matter are now described, by way of example only, and with reference to the accompanying figures, in which:

FIG. 1 shows a schematic block diagram of a communication system according to one embodiment of the invention for providing a set of services relating to a model of an infrastructure comprising assets belonging to different engineering domains;

FIG. 2 shows an example graph of a model of an infrastructure comprising assets belonging to different engineering domains according to one embodiment of the invention; and

FIG. 3 shows a flow chart illustrating a method for providing a set of services relating to a model of an infrastructure comprising physical assets belonging to different engineering domains according to one embodiment of the invention.

The same reference number represents the same element or the same type of element on all drawings.

It should be appreciated by those skilled in the art that any block diagrams herein represent conceptual views of illustrative systems embodying the principles of the present subject matter. Similarly, it will be appreciated that any flow charts, flow diagrams, state transition diagrams, pseudo code, and the like represent various processes which may be substantially represented in computer readable medium and so executed by a computer or processor, whether or not such computer or processor is explicitly shown.

### DESCRIPTION OF EMBODIMENTS

The figures and the following description illustrate specific exemplary embodiments of the invention. It will thus be appreciated that those skilled in the art will be able to devise various arrangements that, although not explicitly described or shown herein, embody the principles of the invention and are included within the scope of the invention. Furthermore, any examples described herein are intended to aid in understanding the principles of the invention, and are to be construed as being without limitation to such specifically recited examples and conditions. As a result, the invention is not limited to the specific embodiments or examples described below, but by the claims and their equivalents.

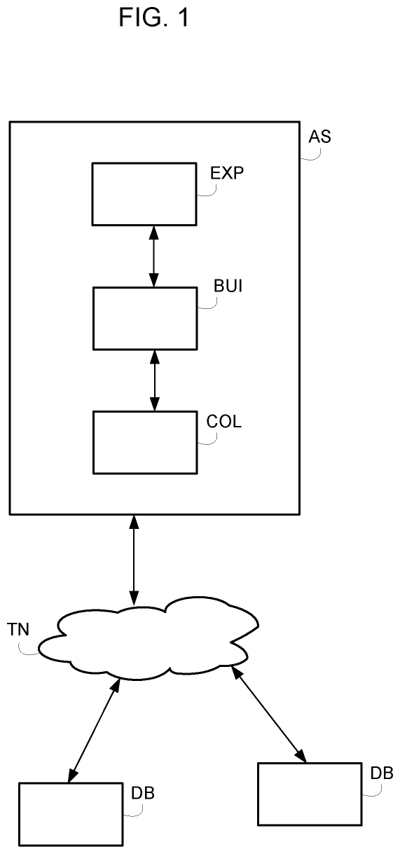

Referring to FIG. 1, an application server AS can communicate with databases DB respectively associated with different engineering domains that are related to a same infrastructure.

An engineering domain deals with a variety of implementation engineering frameworks (hydraulics, mechanics, electronics, electrical, communications) and can be managed by one or more dedicated applications that set the choice of appropriate architecture modelling frameworks and languages.

An infrastructure, such as a plant, comprises assets, like physical assets, that belong to different engineering domains. For example, a plant may present different engineering domains like a process engineering, automation engineering, electrical engineering, network engineering. . . . The process engineering manages process equipment as assets like robot, tank, pump, valve. The automation engineering manages automation equipment as assets like motor controller, IO module. The electrical engineering manages electrical equipment as assets like circuit breaker, switch gear. The network domain manages assets like Ethernet switches and routers.

An asset is an object that performs a job. For example, it can be a physical object, or a virtual or simulated object. For example, an asset can be a transmitter or a pipe or compound, eventually consisting of multiple sub-assets. An asset can be related to any number of other assets. An asset can define signals relating to dynamic, time-varying quantities—which are names and pointers to variables in the system. Such signals contain attributes to define units, ranges, etc. . . . and can point to real-time data, historian time series, and/or simulated versions.

Furthermore, an asset presents a set of attributes, including standard and asset-type specific (e.g location, date of deployment). Mandatory attributes can be a unique name and at least one class of equipment (eg. Pump, motor, controller . . . ). For example, the attributes of an asset can include the following ones: an asset identifier, an asset name, the engineering domain the asset belongs to, an URL (Universal Resource Location) pointing to a standard definition of the asset, a serial number.

It is assumed that one asset may be composed by different assets and thus inherits the attributes of the different assets.

In addition to attributes, each asset has at least one relationship with at least one other asset. It is assumed that there exist different kinds of relationship and all relationships can be categorized in at least two types of relationship: composition relationship and connection relationship. Composition relationship is pointing a sub-asset from which the asset is mechanically composed of Connection relationship is pointing a connected asset. Assets may be connected through various kind of connection: electrical/mechanical/network/ . . . In other words, it can be also assumed that the composition relationship defines a link between two assets from physical point of view and a connection relationship defines an interaction between two assets from connection point of view

While composition and connection relationships are the core of the model like a knowledge graph, additional relationships may be added to provide more semantic and context to describe the assets. For example, the location of the asset can be added through a relationship “IsLocated”.

The relationships between assets can be represented by a defined ontology based on triplets composed of subject, relation and object. The relation can be defined by a URI (Universal Resource Identifier), the subject can be an asset identifier and the object can be another asset identifier.

For example, according to the language of the defined ontology, the composition relationship comprises at least one of the following relations in a non-limiting way: hasPhysicalPart, isPhysicalPartOf, hosts, isHostedIn, hasLocation.

For example, according to the language of the defined ontology, the connection relationship comprises at least one of the following relations in a non-limiting way: hasPipingConnectionTo, isElectricallyConnectedTo, controls, monitors, communicatesWith.

For example, an agitator identified by the asset identifier TR1M01 is considered to be a physical part of a tank identified by the asset identifier TR1. The triplet corresponding to this composition relationship can be the following: (TR1, hasPhysicalPart, TR1M01).

For example, a current transformer identified by the asset identifier TC5 is considered to be electrically connected to a power transformer identified by the asset identifier PTR1. The triplet corresponding to this composition relationship can be the following: (TC5, isElectricallyConnectedTo, PTR1).

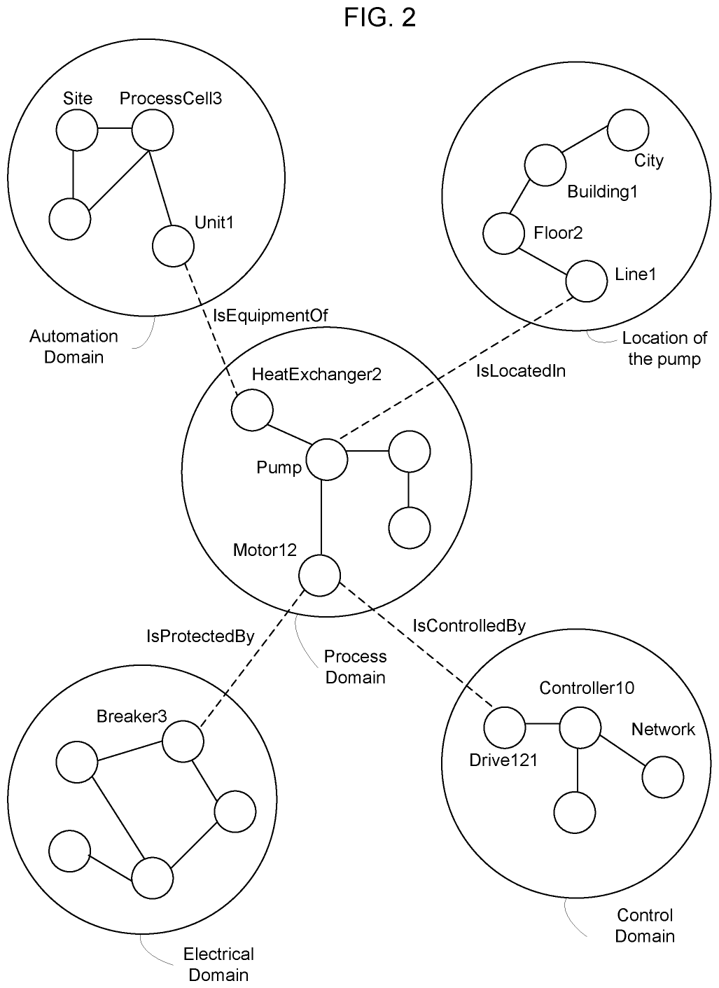

It is assumed that at least one asset belongs or is connected to at least two different engineering domains. For example, in reference to FIG. 2, the relationships between assets are represented by a model under the form of a graph containing nodes corresponding to asset identifiers and edges corresponding to asset relationships between asset identifiers. An asset like a motor identified by Motor12 belongs to the “Process Domain”, and is connected to both “Control Domain” and “Electrical Domain”. The Process Domain contains at least assets like “Motor12”, “Pump” and “HeatExchanger2”. The “Automation Domain” contains at least assets like “Unit1”, “ProcessCell3” and “Site”. The “Control Domain” contains at least assets like “Drive121”, “Controller10”, while the “Electrical Domain” contains Breaker3.

The asset Motor12 of the “Process Domain” has a connection relationship “IsProtectedBy” with the asset Breaker3 of the Electrical Domain and has a connection relationship “Iscontrolled” with the asset Drive121 of the “Control Domain”.

Also in the “Process Domain”, the asset HeatExchanger2 has a composition relationship “IsEquipmentOf” with the asset Unit1 of the Automation Domain”. The asset Pump has another relationship “IsLocatedIn” with the asset Line1 of the engineering domain “Location of the pump”.

In one embodiment for each engineering domain, a database associated with the engineering domain can store the sets of attributes of assets of the engineering domain and the relationships between the assets.

Each engineering domain is associated with at least one dedicated software application allowing access to attributes of assets of the engineering domain, and the set of services is delivered by dedicated applications associated with engineering domains

It is assumed that a common ontology is used across the different engineering domains as a general purpose vocabulary in terms of a reference dictionary, allowing interoperability between the dedicated applications across the different engineering domains. The language used for the naming of some attributes is thus recognized by the dedicated applications across the different engineering domains. Also the language used for the relationship between assets across the different engineering domains satisfies a common model. In parallel, each engineering domain may use specific concepts (like a taxonomy for classifying assets) and a dedicated ontology for exploiting some attributes of the assets of the engineering domain.

Referring back to FIG. 1, the application server AS includes a collector module COL, a builder module BUI and an exploitation module EXP.

The application server AS can communicate with a set of communication devices through a telecommunication network TN. The telecommunication network may be a wired or wireless network, or a combination of wired and wireless networks. The telecommunication network can be associated with a packet network, for example, an IP (“Internet Protocol”) high-speed network such as the Internet or an intranet, or even a company-specific private network.

The collector module COL is configured to retrieve information about assets from different engineering domains. The collector module COL retrieves a first set of data comprising sets of attributes associated with assets. Especially, the first set of data comprises asset identifiers of assets that are respectively associated with sets of attributes of assets. The collector module COL further determines a second set of data comprising relationships between assets. Especially, the second set of data contains asset relationships between asset identifiers. For example, this second set of data can be determined by retrieving it automatically or manually from a database or by a tool analyzing and extracting relationships between assets.

In one embodiment, the retrieval operation may be based on an application interface to display input prompts to an operator to enter the required data. It may also be executed by loading a file containing information about assets. The retrieval operation may be a combination thereof, where said file is loaded and an operator is prompted to confirm the information.

In another embodiment, the collector module COL retrieves automatically the asset information (sets of attributes associated with assets and relationships between assets) from databases DB. The way to retrieve the asset information and the format of the asset information may depend on the kind of engineering domain it relates to. In one embodiment, the collector module COL may retrieve the asset information relating to an engineering domain from an existing domain knowledge graph associated to this latter.

The builder module BUI is configured to build a model for each engineering domain, the model comprising assets identifiers that are linked between them based on the asset relationships of the second set of data. For an engineering domain, such model is called an engineering domain model and is considered to be a set of data that can be accessed and exploited by at one or more dedicated applications for example for analytics, operation or maintenance.

Furthermore, the builder module BUI is configured to determine one or more asset identifiers that belong or are connected to at least two different engineering domain models and to link the models of said at least two different engineering domain models via said at least one asset identifier. In this way, the builder module BUI is able to link the different engineering domain models and thus to build a global semantic model for the infrastructure.

In one embodiment, the semantic model for the infrastructure provides a standardized architecture for the modelling of the hierarchies for the infrastructure assets which can be used by a plurality of different users that are in a business relation to the assets of the infrastructure.

In one embodiment, the engineering domain model corresponds to a domain knowledge graph, wherein nodes of the graph correspond to asset identifiers and edges of the graph correspond to asset relationships between asset identifiers. It is assumed that the domain knowledge graph is a programmatic way to model a knowledge domain for example with the help of subject-matter experts, data interlinking, and machine learning algorithms.

The exploitation module EXP provides a set of services using sets of attributes associated with asset identifiers that belong to different engineering domain models.

In one embodiment, the semantic model is represented by a graph and the exploitation module EXP provides a tool allowing a user to navigate in the graph to access different nodes and thus specific asset information in a given engineering domain.

In one embodiment, the exploitation module EXP provides a tool for analytics, for example for root cause analysis across engineering domains.

In one embodiment, each engineering domain is associated with at least one dedicated application, also called a tool, allowing access to information relating to the assets of the engineering domain by means of the sets of attributes associated with said assets. The exploitation module EXP connects the applications across the different engineering domains. Thus the exploitation module EXP allows the sharing of asset information among the different applications of the engineering domains.

In the semantic model, one asset identifier can be associated with different facets corresponding respectively to different engineering domains. A facet can be engineering domain specific, with a naming convention, structuration and context specific to a facet application. For example, an asset like a pump can be used in an electrical domain, a process domain and a supervisory control domain. Thus, the asset identifier can be associated with a facet linked to a process domain tool, a facet linked to a supervisory control tool and a facet linked to an electrical domain tool.

A facet corresponds to a specific user concern (process, control infrastructure, supervision, etc. . . . ) and presents the infrastructure information in a display adapted to the customer concern (e.g. a plant hierarchy in a ISA88 view).

In one embodiment, each engineering domain may represent a hierarchy that can be made available to facets. A facet associated with an asset can permit access to a functional view of the asset in a functional hierarchy and another facet associated with the asset can permit access to a physical view of the asset in a physical hierarchy. In one example with a pump, a facet can permit to see that the pump is used in a milk doser in a milk processing in a north plant according to the functional hierarchy. In another example with the pump, a facet can permit to see that the pump is part of a motor in a rotating equipment of a process equipment according to the physical hierarchy. Custom hierarchies can also be created using queries across multiple domains: for example a custom hierarchy would be related to all devices from a vendor by device type.

In one embodiment, some assets present properties allowing an exploitation of information by an application. To this end, a facet is associated with the identifier of the asset. In a graph, a facet is designed to extend the node corresponding to the asset by exposing data and functionalities from one or different engineering domains, eventually filtering and contextualizing them for the asset. By means of a facet and a dedicated application, an external system is able to access the asset information and eventually enrich it by publishing proper business logic results.

An embodiment comprises an application server AS under the form of an apparatus comprising one or more processor(s), I/O interface(s), and a memory coupled to the processor(s). The processor(s) may be implemented as one or more microprocessors, microcomputers, microcontrollers, digital signal processors, central processing units, state machines, logic circuitries, and/or any devices that manipulate signals based on operational instructions. The processor(s) can be a single processing unit or a number of units, all of which could also include multiple computing units. Among other capabilities, the processor(s) are configured to fetch and execute computer-readable instructions stored in the memory.

The functions realized by the processor may be provided through the use of dedicated hardware as well as hardware capable of executing software in association with appropriate software. When provided by a processor, the functions may be provided by a single dedicated processor, by a single shared processor, or by a plurality of individual processors, some of which may be shared. Moreover, explicit use of the term “processor” should not be construed to refer exclusively to hardware capable of executing software, and may implicitly include, without limitation, digital signal processor (DSP) hardware, network processor, application specific integrated circuit (ASIC), field programmable gate array (FPGA), read only memory (ROM) for storing software, random access memory (RAM), and non volatile storage. Other hardware, conventional and/or custom, may also be included.

The memory may include any computer-readable medium known in the art including, for example, volatile memory, such as static random access memory (SRAM) and dynamic random access memory (DRAM), and/or non-volatile memory, such as read only memory (ROM), erasable programmable ROM, flash memories, hard disks, optical disks, and magnetic tapes. The memory includes modules and data. The modules include routines, programs, objects, components, data structures, etc., which perform particular tasks or implement particular abstract data types. The data, amongst other things, serves as a repository for storing data processed, received, and generated by one or more of the modules.

A person skilled in the art will readily recognize that steps of the methods, presented above, can be performed by programmed computers. Herein, some embodiments are also intended to cover program storage devices, for example, digital data storage media, which are machine or computer readable and encode machine-executable or computer-executable programs of instructions, where said instructions perform some or all of the steps of the described method. The program storage devices may be, for example, digital memories, magnetic storage media, such as a magnetic disks and magnetic tapes, hard drives, or optically readable digital data storage media.

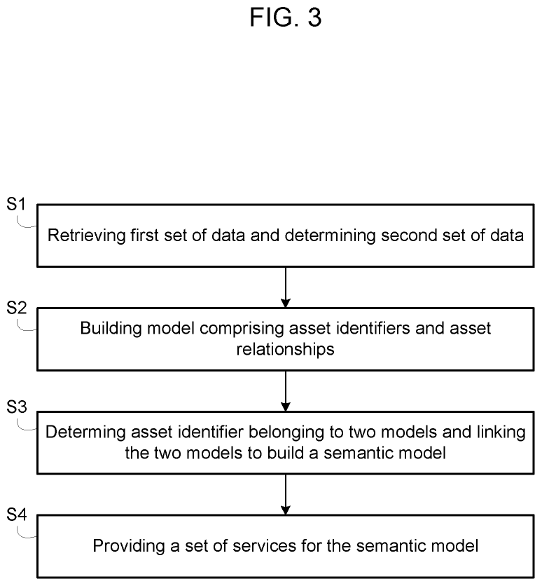

With reference to FIG. 3, a method for providing a set of services relating to a semantic model of an infrastructure according to one embodiment of the invention comprises steps S1 to S4.

In step S1, the collector module COL of the application server AS retrieves sets of attributes associated with assets for each engineering domain of the infrastructure. The collector module stores a first set of data comprising asset identifiers of assets respectively associated with sets of attributes. The collector module COL further determines a second set of data comprising asset relationships between asset identifiers of the first set of data.

The assets can be physical assets of the infrastructure. In an example wherein the infrastructure is an industrial plant, the term asset as used herein generally refers to any equipment, instrument, groupings thereof, devices associated therewith, and the like, that are commonly employed in an industrial plant.

The set of attributes of an asset correspond to semantically meaningful elements that define the asset and that are based on a specific ontology.

In one example, there is provided two assets: a tank and an agitator. The tank may present the following set of attributes:
“TR1” as identifier of asset, “TankR1” as shortname, “RawMilk1 Tank” as longname, “Tank” as instance of class, “process” as engineering domain, “http://data.15926.org/rdl/RDS898290191” as URL for an ontology engine, “SN00000001” as serial number.
   The agitator may present the following set of attributes:
“TR1M01” as identifier of asset, “RMAgitator1” as shortname, “RawMilk1 Agitator” as longname, “Motor” as instance of class, “process” as engineering domain, “http://data.15926.org/rdl/RDS16045622” as URL for an ontology engine, “SN00000002” as serial number.

In this example, the relationships between the tank and the agitator can be represented by the following triplet: TR1 hasPhysicalPart TR1M01.

In step S2, the building module BUI builds an engineering domain model comprising assets identifiers that are linked between them based on the asset relationships of the second set of data.

In one embodiment, the engineering domain model corresponds to a graph, wherein nodes correspond to asset identifiers and edges correspond to asset relationships between asset identifiers. The building module BUI thus uses the engineering domain model to deploy a knowledge graph that can be used to navigate and visualize the relationships between assets. The knowledge graph represents a collection of interlinked entities that enhances the ability of a user to search for desired information. The knowledge graph can be represented in a database using LPG (Labeled Property Graph), RDF (Resource Description Framework), or similar graph models.

In step S3, the building module BUI determines asset identifiers that belongs to at least two different engineering domain models.

The building module BUI links said at least two different engineering domain models via said at least one asset identifier and thus builds a semantic model of the infrastructure based on said at least two different engineering domain models.

In step S4, the exploitation module EXP provides a set of services using sets of attributes associated with asset identifiers that belong to different engineering domain models.

Each engineering domain is associated with one or more dedicated applications allowing access to information relating to the assets of the engineering domain. The exploitation module EXP provides a service by enabling dedicated applications associated with engineering domains to access the information relating to the assets.

In one example, a query display screen of a tool is provided to a user that can search for data by typing natural language queries. For example, the user may ask the tool to display requested alarms either graphically or in text form by displaying the alarms' identifiers. The tool may highlight all common assets for the alarms in the knowledge graph.

In another example, a user or plant operator can also enter commands to initiate operations. The tool may interpret commands written in natural language. For example, to instruct the tool to initiate filling up an asset like a tank labeled “Tank1”, the command “Fill Tank1” may be entered into a command bar.

In another example, a RESTful Application Program Interface may be generated to permit downstream applications to extract information from the knowledge graph.

As different engineering domains are now connected, a user or plant operator can identify a root cause in one engineering domain for an alarm occurred in another engineering domain.

Although the present invention has been described above with reference to specific embodiments, it is not intended to be limited to the specific form set forth herein. Rather, the invention is limited only by the accompanying claims and, other embodiments than the specific above are equally possible within the scope of these appended claims.

Furthermore, although exemplary embodiments have been described above in some exemplary combination of components and/or functions, it should be appreciated that, alternative embodiments may be provided by different combinations of members and/or functions without departing from the scope of the present disclosure. In addition, it is specifically contemplated that a particular feature described, either individually or as part of an embodiment, can be combined with other individually described features, or parts of other embodiments.

1. A method for providing a set of services relating to a semantic model of a plant infrastructure comprising assets belonging to different engineering domains, the method comprising:
for each engineering domain, retrieving asset identifiers respectively associated with assets of the engineering domain and with sets of attributes and determining asset relationships between said asset identifiers,
for each engineering domain, building an engineering domain model comprising assets identifiers that are linked between them based on said asset relationships,
determining at least one asset identifier that belongs or is connected to at least two different engineering domain models and linking said at least two different engineering domain models via said at least one asset identifier to build a semantic model of the infrastructure, and
providing a set of services for the semantic model of the infrastructure, the services using sets of attributes associated with asset identifiers that belong to different engineering domain models.

2. The method according to claim 1, wherein each engineering domain is associated with at least one dedicated application allowing access to information relating to at least one asset of the engineering domain by means of the sets of attributes associated with said at least one asset, and the set of services is delivered by dedicated applications associated with engineering domains.

3. The method according to claim 1, wherein asset relationships are categorized in at least two types of relationship including composition relationship and connection relationship, wherein composition relationship defines physical link between assets and connection relationship defines physical interaction between assets.

4. The method according to claim 1, wherein the engineering domain model corresponds to a domain knowledge graph, wherein nodes correspond to asset identifiers and edges correspond to asset relationships between asset identifiers.

5. The method according to claim 4, wherein a tool is provided to navigate through the domain knowledge graph and to interface with the dedicated applications of the engineering domains.

6. The method according to claim 1, wherein the set of attributes of assets correspond to semantically meaningful elements.

7. The method according to claim 1, wherein the asset relationship is defined by a triple composed of one asset, a relationship and another asset.

8. The method according to claim 1, wherein each engineering domain is associated with a domain ontology defining the format of the set of attributes and of the asset relationships.

9. The method according to claim 1, wherein the assets comprise physical assets.

10. An application server for providing a set of services relating to a semantic model of an infrastructure comprising assets belonging to different engineering domains, the application server comprising:
means for retrieving, for each engineering domain, asset identifiers respectively associated with assets of the engineering domain and with sets of attributes and for determining asset relationships between said asset identifiers,
means for building, for each engineering domain, an engineering domain model comprising assets identifiers that are linked between them based on said asset relationships,
means for determining at least one asset identifier that belongs or is connected to at least two different engineering domain models and linking said at least two different engineering domain models via said at least one asset identifier to build a semantic model of the infrastructure, and
means for providing a set of services for the semantic model of the infrastructure, the services using sets of attributes associated with asset identifiers that belong to different engineering domain models.

11. A non-transitory computer-readable medium having embodied thereon a computer program for executing the method according to claim 1.
